(19) United States
(12) Patent Application Publication
(10) Pub. No.: US 2012/0118725 A1
(43) Pub. Date: May 17, 2012

(54) FILM FORMING METHOD AND FILM FORMING APPARATUS

(75) Inventors: Naoki Morimoto, Susono-shi (JP); Junichi Hamaguchi, Susono-shi (JP); Kazumasa Horita, Susono-shi (JP); Naoki Takeda, Susono-shi (JP)

(73) Assignee: ULVAC, INC., Chigasaki-shi (JP)

(21) Appl. No.: 13/321,605

(22) PCT Filed: May 20, 2010
(86) PCT No.: PCT/JP2010/003406

§ 371 Date: Feb. 3, 2012

(30) Foreign Application Priority Data
May 20, 2009 (JP) 2009-121894

(51) Int. Cl. C23C 14/35

(52) U.S. Cl. 204/192.12; 204/298.16

(57) ABSTRACT

A film forming method of forming a coating on a surface of an object to be processed includes disposing a target forming a base material of the coating and the object to be processed in a chamber so as to face each other, and generating a magnetic field through which a vertical line of magnetic force locally passes from a sputter surface of the target toward a surface to be film formed of the object to be processed at predetermined intervals; generating plasma in a space between the target and the object to be processed by introducing a sputter gas into the chamber, controlling a gas pressure in the chamber to a range of 0.3 Pa to 10.0 Pa, and applying a negative DC voltage to the target; and inducing and depositing the sputter particles on the object to be processed and forming the coating, while controlling flying direction of the sputter particles generated by sputtering the target.

### TECHNICAL FIELD

The present invention relates to a method of forming a coating on a surface of an object to be processed and an apparatus thereof. Specifically, the present invention relates to a method of forming a coating using a sputtering method that is a kind of a thin film forming method, and a DC magnetron type film forming apparatus.

Priority is claimed on Japanese Patent Application No. 2009-121894, filed May 20, 2009, the content of which is incorporated herein by reference.

### BACKGROUND ART

In related art, for example, in a film forming process in the manufacturing of a semiconductor device, a film forming apparatus using a sputtering method (hereinafter, referred to as “sputtering apparatus”) is used. In the sputtering apparatus of such an application, along with a reduction in size of a wiring pattern of recent years, in regard to a micro hole of a high aspect ratio, it is strongly required to form a film over the whole surface of the substrate to be processed with good coating property characteristics (coatability), that is, an improvement in coverage is strongly required.

Generally, in the sputtering apparatus mentioned above, for example, at the back (a side that reverses the sputter surface) of a target, a magnetic assembly is disposed in which a plurality of magnets are provided so that polarities are alternately changed. A tunnel-shaped magnetic field is generated at the front (the sputter surface side) of the target through the magnetic assembly. Thereby, the electrons produced as a result of ionization at the front of the target and secondary electrons generated by the sputtering can be caught. As a result, electron density at the front of the target is increased, and the plasma density is increased.

However, in this kind sputtering apparatus, among the targets, the target is preferentially sputtered in a region affected by the magnetic field. For this reason, from the viewpoint of an improvement in stability of an electric discharge, in use efficiency of the target or the like, for example, when the region is in the vicinity of the center of the target, an amount of erosion of the target during sputtering is increased in the vicinity of the center. In such a case, target material particles (for example, metallic particles, hereinafter, referred to as “sputter particles”) sputtered from the target are incident to an outer peripheral portion of the substrate at a tilted angle and are attached thereto. As a consequence, in the case of being used in the film formation of the application mentioned above, particularly, it is known from the past that a problem of asymmetry of the coverage occurs at the outer peripheral portion of the substrate.

Furthermore, in the sputtering apparatus of the related art, since the sputter particles discharged from the target during film formation are tilted and are scattered, there was a problem in that the sputter particles are attached to and deposited on, for example, an exposed surface in a film forming chamber such as a anti-attachment plate as well as the surface of the substrate. For that reason, when the attachment and the deposition of the thin film to the exposed surface are repeated, the particles such as from the peeling-off or the cracking of the thin film are generated due to the internal stress or the self-weight. In addition, a shape defect or a structure defect such as a micro protrusion is formed on the manufactured thin film is generated, whereby there is a need to frequently perform the maintenance of the film forming chamber.

Thus, in order to solve the problem, for example, Patent Document 1 discloses a sputtering apparatus that includes a plurality of cathode units. In the sputtering apparatus according to Patent Document 1, a first sputtering target is placed above a stage such that substantially parallel to the surface of the stage, in which the substrate is mounted on the stage in a vacuum chamber, and a second sputtering target is placed obliquely above the stage so as to be tilted to the surface of the stage.

Meanwhile, as a technique of maintaining the inner portion of the vacuum chamber, techniques as below are suggested.

For example, Patent Document 2 discloses a technique of etching a thin film of constitutive substances of the target attached to an inner wall surface or the like of the vacuum chamber, by mounting a dummy substrate on a surface of the electrostatic chuck plate which fixes the substrate, bringing the dummy substrate into close contact with the surface by the electrostatic adsorption, and then introducing a cleaning gas such as fluorine gas into a vacuum bath.

Furthermore, Patent Document 3 discloses a technique of removing particles from the electrostatic chuck plate, by performing a sulfuric acid hyper-hydration cleaning and an ammonia hyper-hydration cleaning on the semiconductor wafer.

In addition, for example, Patent Document 4 discloses a film forming apparatus that includes a shutter mechanism blocking a material from a film forming material supply source (a target), and periodically cleans or switches a shutter plate that constitutes the shutter mechanism.

However, the apparatus disclosed in Patent Document 1 requires a plurality of cathode units to be disposed in the vacuum chamber. Thus, since an apparatus configuration is complicated and there is a need for a sputter power source or a magnetic assembly depending on the number of the targets, there is a disadvantage in that the number of components is increased, which causes a high cost.

Furthermore, none of the techniques disclosed in Patent Document 2 to Patent Document 4 is a technique of suppressing the maintenance frequency of the film forming chamber.

In addition, the techniques disclosed in Patent Document 2 to Patent Document 4 have a disadvantage that the apparatus configuration is complicated, which also causes the high cost.

### PRIOR ART DOCUMENTS

### Patent document

[Patent Document 1] Japanese Unexamined Patent application, First Publication 2008-47661
[Patent Document 2] Japanese Unexamined Patent application, First Publication 2003-158175
[Patent Document 3] Japanese Unexamined Patent application, First Publication 2008-251579
[Patent Document 4] Japanese Unexamined Patent application, First Publication H6-299355

### DISCLOSURE OF INVENTION

### Problems to be Solved by the Invention

The present invention was made in view of the above circumstances, and an object thereof is to provide a film forming method and a film forming apparatus that improve a coverage ratio to micro grooves or holes of high aspect ratio with a simple configuration and a low cost, and are able to extend a maintenance cycle of a film forming apparatus.

### Means for Solving the Problems

In order to solve the problem, the present invention adopts the configuration as below.

According to an aspect of the present invention, there is provided a film forming method of forming a coating on a surface of an object to be processed, the method includes disposing a target forming a base material of the coating and the object to be processed in a chamber so as to face each other, and generating a magnetic field through which a vertical line of magnetic force locally passes from a sputter surface of the target toward a surface to be film formed of the object to be processed at predetermined intervals; generating plasma in a space between the target and the object to be processed by introducing a sputter gas into the chamber, controlling a gas pressure in the chamber to a range of 0.3 Pa to 10.0 Pa, and applying a negative DC voltage to the target; and inducing and depositing sputter particles on the object to be processed and forming the coating, while controlling flying direction of the sputter particles generated by sputtering the target.

In the film forming method, the flying direction of the sputter particles may be controlled by adjusting an intensity of the magnetic field.

In the film forming method, the intervals between the vertical lines of magnetic force may be identical in a central region and a peripheral region of the object to be processed.

In the film forming method, the intervals between the vertical lines of magnetic force may be different in a central region and a peripheral region of the object to be processed.

According to another aspect of the present invention, there is provided a film forming apparatus that forms a coating on a surface of an object to be processed, wherein the film forming apparatus includes a chamber in which a target forming a base material of the coating and the object to be processed are disposed so as to face each other and which has an internal space that houses the target and the object to be processed therein; an exhaust mechanism that decompresses an inner portion of the chamber; a first magnetic field generating mechanism that generates a magnetic field in a front space when viewed from a sputter surface of the target; a gas introducing mechanism that has a function of adjusting a flow rate of a sputter gas to be introduced into the chamber; a DC power source that applies a negative DC voltage to the target (or applies the direct voltage to set the sputter surface of the target to a negative electric potential); and a second magnetic field generating mechanism that generates a magnetic field through which a vertical line of magnetic force locally passes from the sputter surface of the target toward the surface to be film formed of the object to be processed at predetermined intervals.

The film forming apparatus according to the present invention further includes a holder in which one or more concave portions are provided at one surface thereof, wherein the target forms a cylindrical shape having a bottom, and is mounted on the concave portion of the holder from a bottom portion side of the target, and the first magnetic field generating mechanism is assembled to the holder so as to generate the magnetic field in an internal space of the target.

### Effects of the Invention

According to the film forming method of the aspect of the present invention, while generating the magnetic field such that the vertical line of magnetic force locally passes from the sputter surface of the target toward the surface to be film formed of the object to be processed at predetermined intervals, the sputter gas is introduced into the chamber, and the gas pressure in the chamber is controlled to a range of 0.3 Pa to 10.0 Pa. Thus, a mean free path (MFP) of the sputter particles generated by sputtering the target in the chamber space drops due to the high pressure process gas of the range of 0.3 Pa to 10.0 Pa, straightness is weakened, the flying direction thereof is controlled so as to follow a direction of the vertical line of magnetic force according to the line of magnetic force of the magnetic field generated between the sputter surface of the target and the object to be processed, whereby directivity can be increased so that a film is selectively formed only in a predetermined region, or the film is not selectively formed in a predetermined region. Furthermore, the sputter particles are obliquely scattered, whereby, for example, it is possible to greatly reduce the attachment or the deposition to a portion other than the surface to be film formed of the object to be processed such as an anti-attachment plate.

Thus, it is possible to realize an improvement in coverage ratio to a high aspect ratio micro groove or hole, and it is possible to achieve an extension of the maintenance cycle of the film forming apparatus.

According to the film forming apparatus relating to another aspect of the present invention, the film forming apparatus includes at least a gas introducing mechanism that includes a function of adjusting the flow rate of the sputter gas to be introduced into the chamber; and a second magnetic field generating mechanism that generates the magnetic field so that the vertical line of magnetic force locally passes from the sputter surface of the target toward the surface to be film formed of the object to be processed at predetermined intervals. Therefore, since the magnet assembly remains which determines a region where the target is preferentially sputtered, the use efficiency of the target does not drop. Furthermore, since a plurality of cathode units is not provided in the sputtering apparatus like in the related art, it is possible to reduce the manufacturing cost of the apparatus or the running cost.

Thus, it is possible to realize an improvement in coverage ratio to the high aspect ratio micro groove or hole and to provide a film forming apparatus having an improved maintenance cycle with a simple configuration and low cost.

### BRIEF DESCRIPTION OF THE DRAWINGS

FIG. 1 is a schematic cross-sectional view that describes a structure of a film forming apparatus according to a first embodiment of the present invention.

FIG. 2 is a cross-sectional view that describes a structure of a holder (a cathode unit) according to the first embodiment that includes a target and a first magnetic field generating mechanism.

FIG. 3 is a transverse cross-sectional view of the holder shown in FIG. 2.

FIG. 4 is a partially enlarged cross-sectional view that describes the sputtering in a space in an inner portion of the target.

FIG. 5 is a schematic diagram that describes a vertical line of magnetic force which is generated by a second magnetic field generating mechanism.

FIG. 6 is a schematic diagram that describes another vertical line of magnetic force which is generated by the second magnetic field generating mechanism.

FIG. 7 is a schematic cross-sectional view that describes a structure of a film forming apparatus according to a second embodiment of the present invention.

FIG. 8 is a cross-sectional view that describes a structure of a holder (a cathode unit) according to the second embodiment which includes a target and a first magnetic field generating mechanism.

FIG. 9 is a transverse cross-sectional view of the holder shown in FIG. 8.

FIG. 10 is a graph that describes a film forming property depending on the process pressure.

FIG. 11A is a schematic cross-sectional view that shows a state of a micro hole of a high aspect ratio in which the gas pressure in the chamber is changed and the film is formed.

FIG. 11B is a schematic cross-sectional view that shows a state of a micro hole of a high aspect ratio in which the gas pressure in the chamber is changed and the film is formed.

FIG. 11C is a schematic cross-sectional view that shows a state of a micro hole of a high aspect ratio in which the gas pressure in the chamber is changed and the film is formed.

FIG. 12 is a diagram that describes a film forming property depending on presence or absence of the vertical magnetic field.

### DETAILED DESCRIPTION OF THE PREFERRED EMBODIMENTS

Next, a film forming apparatus and a film forming method according to the embodiments of the present invention will be described based on the drawings.

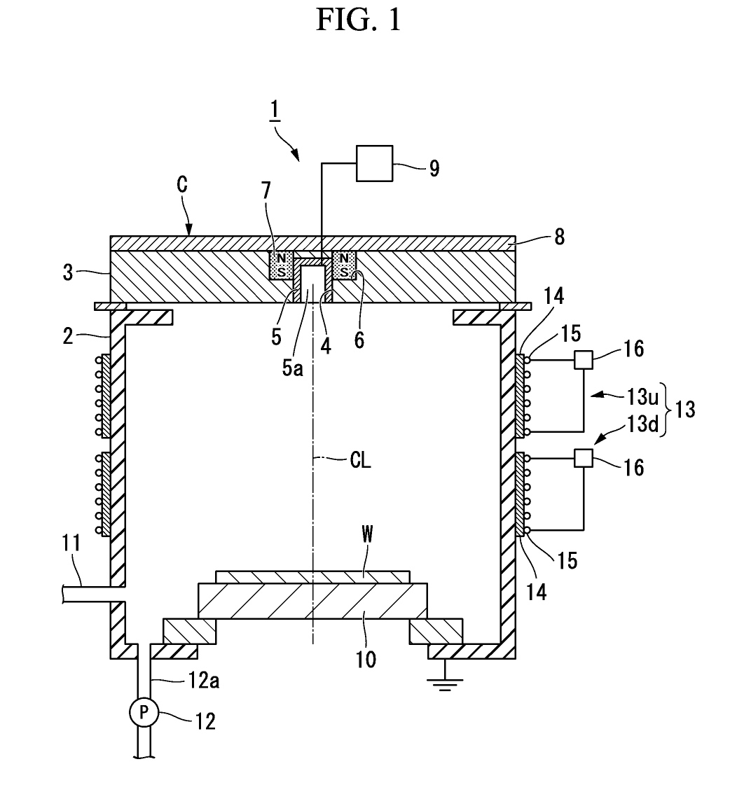

A film forming apparatus 1, which performs the film forming method according to the present invention, is an apparatus that forms a coating on a surface of a substrate W as an object to be processed using a sputter method. As shown in FIGS. 1 to 3, the film forming apparatus 1 according to the present embodiment at least includes a chamber 2, a cathode unit C, a first magnetic field generating mechanism 7, a DC power source 9, a gas introducing mechanism 11, an exhaust mechanism 12, and a second magnetic field generating mechanism 13.

In addition, in the description as below, a ceiling portion side of the chamber 2 is called “upper side” and a bottom portion side thereof is called “lower side”.

### First Embodiment

The chamber 2 is an air-tight container capable of forming a vacuum environment. The chamber 2 disposes a substrate W and a target 5 so as to face each other and has an internal space in which the substrate W and the target 5 are storaged.

Furthermore, a stage 10 is disposed in a bottom portion of the chamber 2 so as to face the target 5, whereby the substrate W can be positioned and held thereon.

In addition, the chamber 2 is electrically connected to a ground electric potential. Herein, the expression “connected to the ground electric potential” indicates a ground electric potential condition or an earth condition.

The cathode unit C includes a disc-shaped holder 3 made from a material having conductivity. The holder 3 can also be made from the same material as a target 5 described later. The target 5 is a hollow type (a cylindrical shape having a bottom; a cross section of an upside down U shape) target 5.

A case will be described where the cathode unit C including a hollow type (the upside down U shape) target 5 according to the present embodiment is attached to a ceiling portion of the chamber 2.

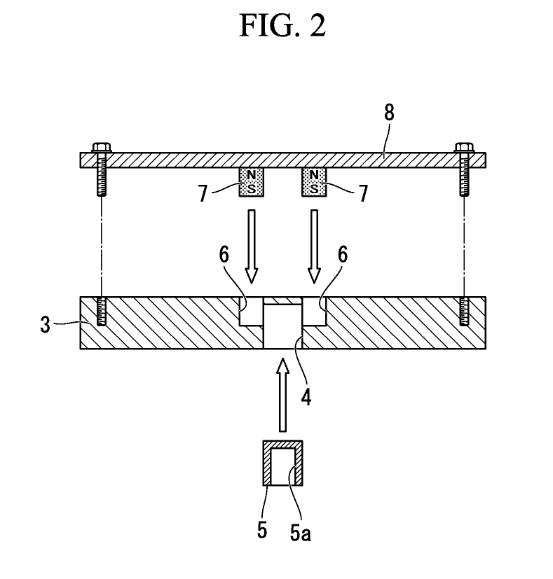

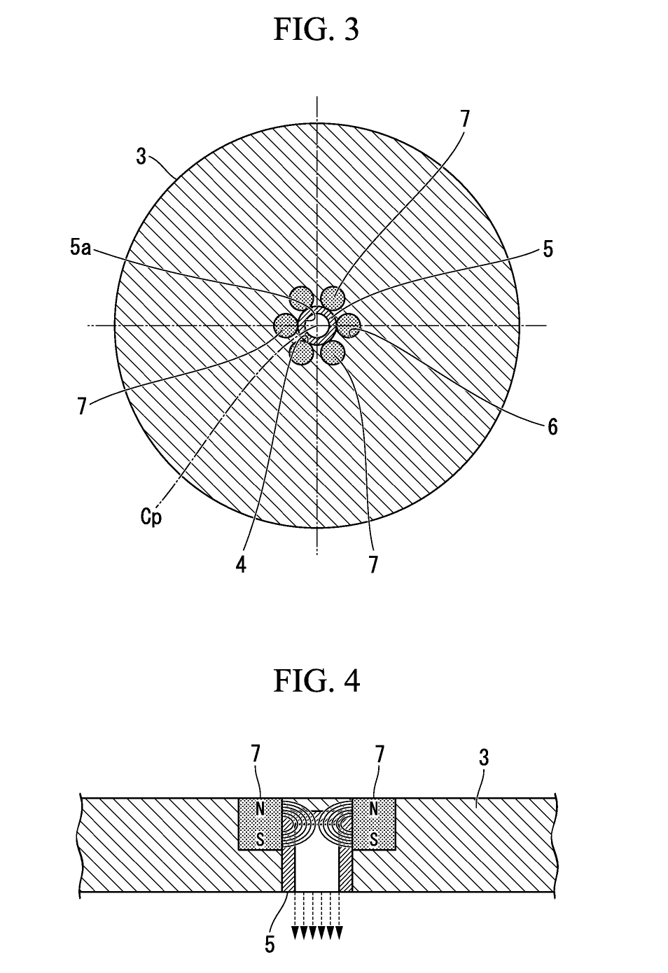

The target 5 is made of a material that is suitably selected depending on the composition of the thin film formed on the substrate W to be processed, for example, Cu, Ti or Ta. The target 5, for example, has an exterior of a cylindrical shape having a bottom in which a discharging space 5a is formed in the inner portion thereof. As shown in FIG. 2, the target 5 is mounted in a concave portion 4 formed in the holder 3, and is disposed at an upper position (inside of the ceiling side) in the internal space of the chamber 2. The target 5 is connected to a DC power source 9 provided outside the chamber 2. The concave portion 4 is formed on a lower surface of the holder 3, and is concentric with a center Cp (see FIG. 3) of the holder 3, and the concave portion 4 has a circular shape when viewed from the plane.

Furthermore, the target 5 is fitted to the concave portion 4 from the bottom side in a freely attachable and detachable manner. That is, an opening of the target 5 faces the substrate side. When the target 5 is fitted in the concave portion 4, the lower surface of the target 5 coincides with the lower surface of the holder 3 on a horizontal surface (the surfaces are identical to each other). That is, the length of the target 5 coincides with the length of the concave portion 4. After fitting the target 5 in the concave portion 4 of the holder 3, a mask plate (not shown) including an opening smaller than an opening area of the target 5 is attached to the lower surface of the holder 3. When attaching the cathode unit C to the ceiling portion of the chamber 2, the mask plate prevents the target 5 from being detached from the concave portion 4. In this case, the mask plate can be made from, for example, the same material as the target 5.

The first magnetic field generating mechanism 7 is, for example, a magnet formed in a rod shape, a cylinder shape, or a prismatic shape, and generates the magnetic field in a front space when viewed from the sputter surface of the target 5. The first magnetic field generating mechanism 7 is attached to the holder 3, and generates the magnetic field in the internal space of the target 5. The first magnetic field generating mechanism (the magnet) 7 is inserted into an accommodation hole 6 formed on an upper surface of the holder 3. The accommodation hole 6 is established on the upper surface of the holder 3 and is extended in a thickness direction of the holder 3. Thus, the accommodation hole 6 is disposed in a depth direction of the concave portion 4, and the accommodation hole 6 capable of accommodating the first magnetic field generating mechanism 7 is established on a surface (a surface of an opposite side) reversing one side formed with the concave portion 4, whereby the first magnetic field generating mechanism 7 can simply be assembled to the holder 3. That is, the concave portion 4 is formed on one surface of the holder 3 and the accommodation hole 6 is formed on another surface of the holder 3, whereby the first magnetic field generating mechanism 7 can simply be assembled to the holder 3. In the description as below, in some cases, the first magnetic field generating mechanism 7 is described as a magnet 7.

In the present embodiment, as shown in FIG. 3, around one concave portion 4, six accommodation holes 6 are formed in a circumferential direction of the concentric circle with the concave portion 4 at equal intervals. Thus, six magnets 7 are formed around one concave portion 4 at equal intervals. Furthermore, as shown in FIG. 1, a depth of the accommodation hole 6 from the upper surface of the holder 3 is set such that the magnets 7 are positioned to the depth position of at least ⅓ from the bottom portion of the target 5. That is, the accommodation holes 6 are formed up to the position of the depth of about ⅓ of the target 5.

The magnets 7 are designed so that a strong magnetic field of 500 gauss or more is generated in the internal space 5a of the target 5 upon being disposed around the concave portion 4. In addition, the magnets 7 are erected so that the polarities thereof are identical to each other at a predetermined positions of the disc-shaped support plate 8 (for example, the polarity of the support plate 8 is set to N pole).

Moreover, when joining the support plate 8 to the upper surface of the holder 3, each magnet 7 is inserted into each accommodation hole 6, whereby each magnet 7 is disposed around the concave portion 4 (see FIG. 2). The support plate 8 is also formed of a material having conductivity, and after both of the support plate 8 and the holder 3 are joined to each other, for example, both of them are fixed to each other by the use of a fastening mechanism such as a bolt. In addition, a mechanism, through which the refrigerant is circulated, is provided in the internal space of the support plate 8, and may serve as a backing plate that cools the holder 3 with the target 5 inserted thereto during sputtering.

Furthermore, if the magnet (the first magnetic field generating mechanism) 7 is integrally attached to the support plate 8, the magnet 7 is inserted to the accommodation hole 6 by joining the support plate 8 to the upper surface of the holder 3, whereby the magnet 7 as the first magnetic field generating mechanism may further simply be disposed around the concave portion 4.

The DC power source 9 is a so-called sputter power source that applies a negative DC voltage to the target during sputtering (or applies a direct voltage to set the sputter surface of the target to the negative electric potential), and has a known structure. Furthermore, the DC power source 9 is electrically connected to the cathode unit C (the target 5).

The gas introducing mechanism 11 adjusts the flow rate (inflow volume) of the sputter gas to be introduced into the chamber 2, and introduces, for example, the sputter gas such as argon gas via a gas pipe connected to a side wall of the chamber 2. Furthermore, the other end of the gas pipe communicates a gas source via a mass flow controller (not shown).

The exhaust mechanism 12 decompresses the inner portion of the chamber 2, for example, is constituted by a turbo molecule pump, a rotary pump or the like, and is connected to an exhaust port formed on a bottom wall of the vacuum chamber 2. As shown in FIG. 1, upon starting the exhaust mechanism 12, the inner portion of the chamber 2 is subjected to the vacuum-exhaust from the exhaust port via the exhaust pipe 12a.

The second magnetic field generating mechanism 13 generates the magnetic field such that the vertical line M of magnetic force locally passes from the sputter surface of the target 5 toward the surface to be film formed of the substrate W at predetermined intervals.

The second magnetic field generating mechanism 13 includes a coil which is formed by winding a lead wire 15 around a ring-shaped yoke 14 provided at an outer wall side of the chamber 2 around a reference axis CL connecting the target 5 with the substrate W, and a power source device 16 that causes the current to flow in the coil.

In the present embodiment, the coil includes an upper coil 13u disposed at the upside, and a lower coil 13d disposed at the downside.

As a result, the current is caused to flow in the coils 13u and 13d, whereby the vertical magnetic field can be generated such that the vertical line of magnetic force locally passes between the target 5 and the substrate W at predetermined intervals. If the film is formed in this state, the sputter particles from the target 5 are controlled in the flying direction thereof by the vertical magnetic field, whereby the sputter particles can be approximately vertically incident to and be attached to the substrate W. As a consequence, if the film forming apparatus according to the present invention is used in the film forming process in the manufacturing of the semiconductor device, it is possible to form the coating on the surface of the substrate W with satisfactory directivity even in a micro hole of high aspect ratio.

Furthermore, in the second magnetic field generating mechanism 13, by adjusting the intensity of the magnetic field, the flying direction of the sputter particles can be controlled.

Herein, the number of the coils 13 and the diameter or the winding number of the lead wire 15 can be suitably set depending on the size of the target 5, the distance between the target 5 and the substrate W, the rated current value of the power source device 16, or an intensity (gauss) of the magnetic field to be generated (for example, the diameter is 14 mm, and the number of winding is 10).

Furthermore, like the present embodiment, when generating the vertical magnetic field in two coils 13u and 13d disposed up and down, in order to approximately equalize the film thickness distribution in the plane of the substrate W during film formation (approximately equalize the sputter rate in the diameter direction of the substrate W), it is desirable to set the positions of the coils 13u and 13d in the vertical direction such that the distance between a lower end of the upper coil 13u and the target 5 and the distance between an upper end of the lower coil 13d and the substrate W become shorter than the distance up to a middle point Cp of the reference axis. Furthermore, in this case, it is not necessarily required that the distance between the lower end of the upper coil 13u and the target 5 is coincident with the distance between the upper end of the lower coil 13d and the substrate W, and the upper and lower coils 13u and 13d may be provided at the backside of the target 5 and the substrate W.

The power source device 16 has a known structure that includes a control circuit (not shown) capable of arbitrarily changing the current value and the direction of the current to each of the upper and lower coils 13u and 13d. In addition, in order to arbitrarily change the current value and the direction of the current to each of the upper and lower coils 13u and 13d, FIG. 1 shows a configuration provided with a separate power source device 16, but when causing the current to flow in each of the coils 13u and 13d by the same current value and the direction of the current, a configuration may be adopted in which the current is caused to flow by one power source device.

By configuring the film forming apparatus 1 as mentioned above, in the case of sputtering the target 5, when the sputter particles scattered from the target 5 have a positive charge, the flying direction thereof is controlled by the vertical magnetic field from the target 5 to the substrate W, whereby the sputter particles are approximately vertically incident to and attached to the substrate W over the whole surface of the substrate W. As a consequence, if the film forming apparatus 1 is used in the film forming process in the production of the semiconductor device, it is possible to realize an improvement in coverage ratio to the high aspect ratio micro groove or hole.

Next, regarding the film formation using the film forming apparatus 1, an example will be described in which a Cu film as a sheet film is formed by the sputtering by the use of a material formed by forming silicon oxide film (insulation film) on the Si wafer surface as the substrate W subjected to the film formation, and then patterning a micro hole for wiring in the silicon oxide film using a known method.

Firstly, the target 5 is fitted to the concave portion 4 of the lower surface of the holder 3, and the support plate 8 with the magnet 7 erected therein is joined to the upper surface of the holder 3 so that each magnet 7 is inserted into the accommodation hole 6, and the support plate 8 and the holder 3 are fixed to each other, for example, using a bolt, thereby assembling the cathode unit C. Moreover, the cathode unit C is attached to the ceiling portion of the chamber 2.

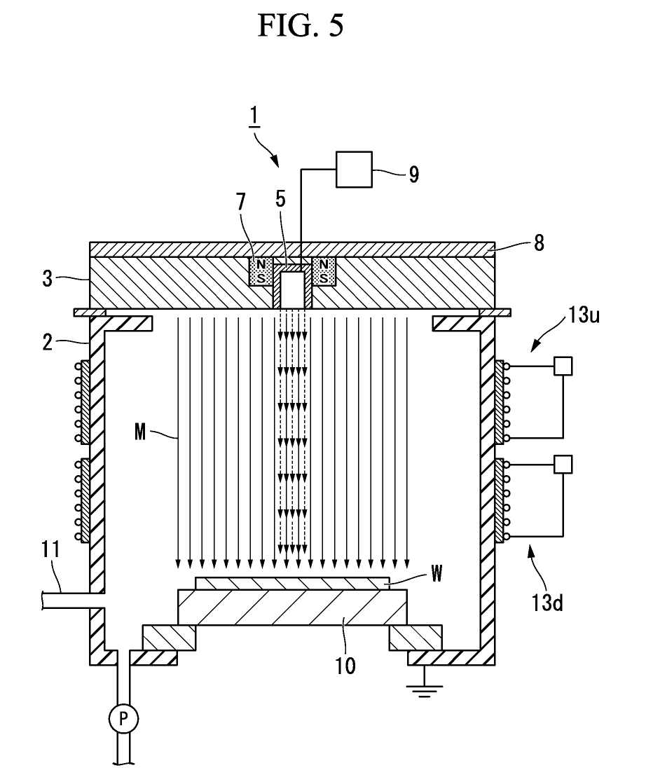

Next, after mounting the substrate W on the stage 10 facing the cathode unit C, the exhaust mechanism (the exhaust pump) 12 is operated, the inner portion of the chamber 2 is subjected to the evacuation up to a predetermined degree of vacuum (for example, 10⁻⁵ Pa), and the power source device 16 is input to cause the current to flow in the coils 13u and 13d, whereby the magnetic field is generated such that the vertical line M of magnetic force (FIG. 5) locally passes from the sputter surface of the target 5 toward the surface to be film formed of the substrate W at predetermined intervals. At this time, in a central region and a peripheral region of the substrate W that is the object to be processed, the intervals between the vertical lines of magnetic force are identical to each other.

Moreover, when the pressure in the chamber 2 reaches a predetermined value, the sputter gas formed of, for example, Ar (argon) gas is introduced into the chamber 2 at a predetermined flow rate (that is, so that the gas pressure in the chamber 2 is controlled in the range from 0.3 Pa to 10.0 Pa), the DC power source 9 is started, and a negative electric potential of a predetermined value is applied to the cathode unit C (power input).

When the negative electric potential is applied to the cathode unit C, a glow discharge is generated in the space of the front of the cathode unit C from the space 5a of the target 5 in the holder 3, and, at this time, the plasma is contained in the space 5a by the magnetic field generated by the magnet 7. When stopping the introduction of the sputter gas in this state, the self-discharge is performed in the space 5a.

Moreover, the argon ions or the like in the plasma crash into the inner wall surface of the target 5 and are sputtered, the Cu atoms are scattered, and the Cu atoms or the ionized Cu ions are discharged from the opening of the lower surface of the target 5 into the chamber 2 toward the substrate W with a high degree of straightness, as indicated by a dotted-arrow in FIG. 4.

When the ionized Cu ions are discharged from the opening of the lower surface of the target 5, the mean free path (MFP) in the chamber space is shortened by the high pressure process gas, and the straightness is weakened. Thus, as shown by an arrow in FIG. 5, according to the shape of the vertical line M of magnetic force locally generated from the sputter surface of the target 5 toward the substrate W at a predetermined space, the flying direction is controlled so as to follow the direction of the line M of magnetic force, whereby, as indicated by the dotted-arrow in FIG. 5, the directivity is enhanced so as to selectively form the film only in a predetermined region (or not selectively form the film in the predetermined region).

As a consequence, at a position (a region including a portion facing the opening of the target 5 and the surroundings thereof) immediately below the opening of the target 5, the film is formed so as to have an extremely high film thickness uniformity, whereby, the film can also be formed with satisfactory coating property even in the high aspect ratio micro hole in a predetermined region of the substrate W.

In addition, at this time, by providing energy by heat, ion radiation or the like, the growth of the thin film can be promoted.

In this manner, in the present embodiment, the substrate W is disposed so as to face the target 5 forming the base material of the coating in the chamber 2, while generating the magnetic field so that the vertical line of magnetic force locally passes from the sputter surface of the target 5 toward the surface to be film formed of the substrate W as the object to be processed at predetermined intervals, the sputter gas is introduced into the chamber 2, and, by controlling the gas pressure in the chamber in the range from 0.3 Pa to 10.0 Pa, the sputter particles having the directivity can be transported from the sputter source toward the substrate. Thus, the sputter particles from the target 5 are changed in the direction thereof by the vertical magnetic field, and are approximately vertically incident to and attached to the substrate W. As a consequence, if the film forming apparatus according to the present embodiment is used in the film forming process of the production of the semiconductor device, in the high aspect ratio micro hole, the film can also be formed over the whole surface of the substrate with a satisfactory coating property, whereby the coverage ratio can be improved.

Thus, if the film forming apparatus according to the present embodiment is used in the film forming process in the production of the semiconductor device, in the high aspect ratio micro hole, the film can also be formed with a satisfactory coating property. Furthermore, since the transportation path of the sputter particles can be controlled, if the sputter particles are controlled so as to be limited only to the substrate, the amount of deposition to a portion other than the substrate such as an anti-attachment plate can greatly be reduced, whereby the extension of the maintenance cycle can be achieved. In addition, since the plurality of cathodes like in the related art is not provided in the film forming apparatus itself, compared to a case where the apparatus configuration is changed, the configuration is simple, and the production cost of the apparatus can be lowered.

In addition, in the present embodiment, a configuration was described as an example in which a rod shape is used as the magnet 7, but, if the strong magnetic field of 500 gauss or more is formed in the space 5a of the target 5, the configuration is not particularly limited. Thus, the space 5a of the target 5 may be disposed so as to surround the target 5 using the ring-shaped magnet. In this case, on the upper surface of the holder 3, an annular accommodation groove capable of accommodating the ring-shaped magnet therein may be established.

Furthermore, in the present embodiment, a configuration was described in which the target 5 is inserted into the holder 3 in a freely attachable or detachable manner in consideration of the mass productivity or the use efficiency of the target, but the holder 3 itself can also serve as the target 5. That is, a configuration may be adopted in which only the concave portion 4 is formed on the lower surface of the holder 3, the magnet 7 is equipped around the concave portion 4, and the inner wall surface of the concave portion 4 is sputtered.

Furthermore, a configuration may be adopted in which a high frequency power source (not shown) having a known structure is electrically connected to the stage, a predetermined bias electric potential is applied to the stage 10, and the substrate W during sputtering, and in the case of forming the sheet layer of Cu, the Cu ions are positively attracted to the substrate, whereby the sputter rate is increased.

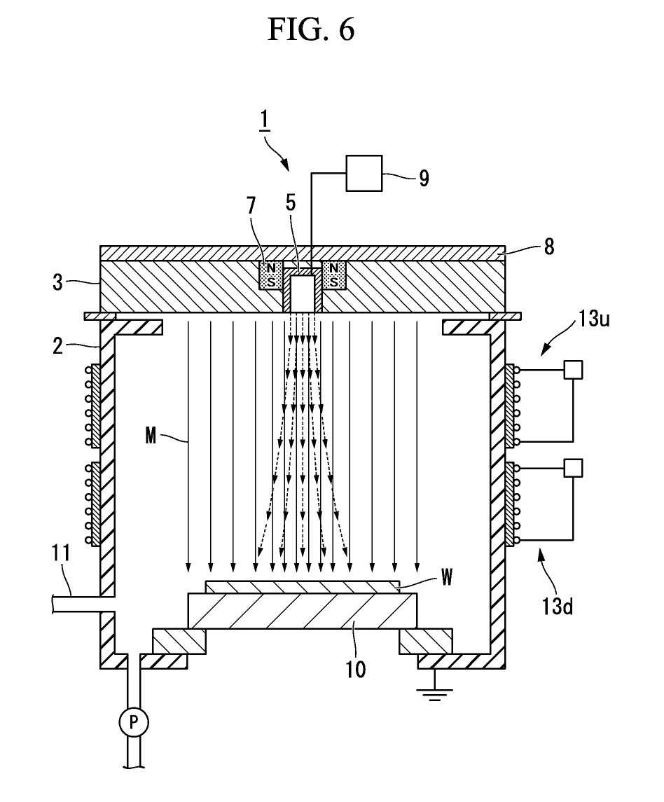

In addition, in the embodiment mentioned above, a case was described where the intervals between the vertical lines M of magnetic force are identical to each other in the central region and the peripheral region of the substrate W. However, by respectively adjusting the electric current value to be applied to the upper and lower coils 13u and 13d by the power source device 16, as shown in FIG. 6, a configuration may be adopted in which the intervals between the vertical lines M of magnetic force are different from each other in the central region and the peripheral region of the substrate W.

In this case, the intensity of the magnetic field is adjusted, and the flying direction of the sputter particles is controlled, whereby the film can be formed in a desired region.

### Second Embodiment

In the first embodiment mentioned above, a configuration was described which includes a cathode unit with only one target (material) attached to one side of the holder, but the present invention is not limited thereto.

Thus, in the present embodiment, a film forming apparatus will be described which includes the cathode unit with a plurality of targets (materials) attached to one side of the holder.

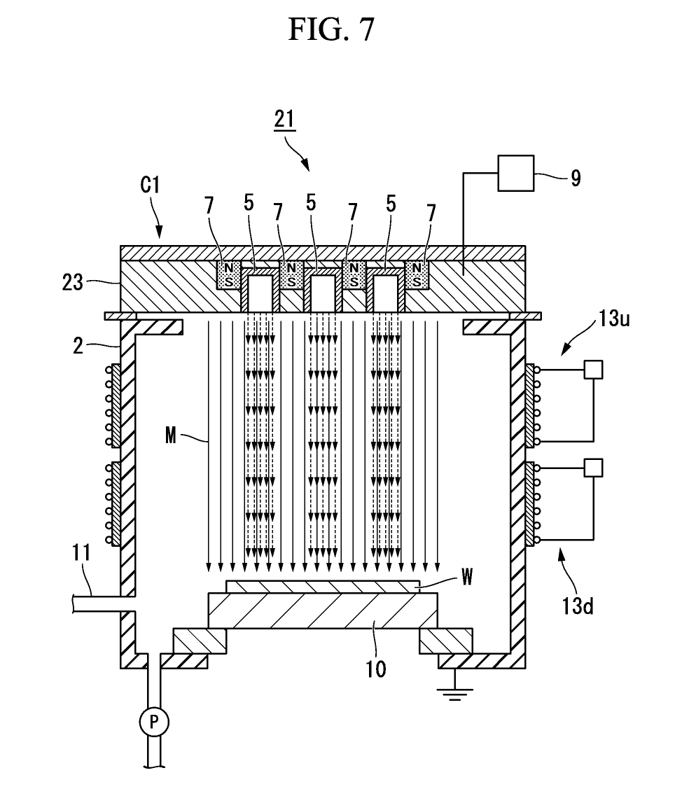

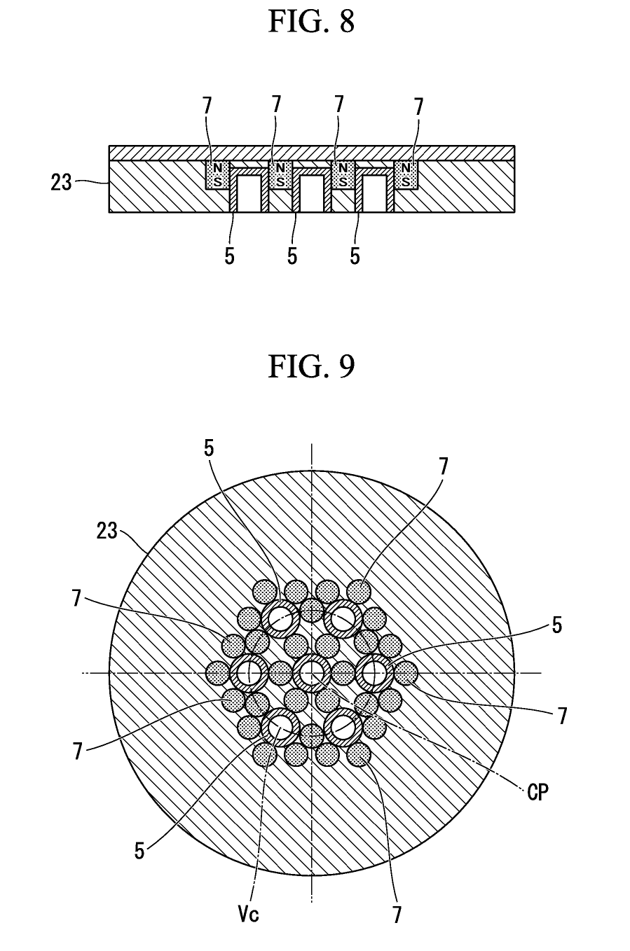

As shown in FIGS. 7 to 9, the film forming apparatus 21 according to the present embodiment performing the film forming method of the present invention is an apparatus that forms the coating on the surface of the substrate W as the object to be processed using the sputtering method. The film forming apparatus 21 includes at least the chamber 2, the cathode unit C1, the first magnetic field generating mechanism 7, the DC power source 9, the gas introducing mechanism 11, the exhaust mechanism 12, and the second magnetic field generating mechanism 13.

In addition, in a second embodiment described below, portions different from the first embodiment mentioned above will mainly be described. Thus, the same components as the first embodiment will be denoted by the same reference numerals, and the descriptions thereof will be omitted and not be described in detail.

The cathode unit C1 includes a disc shaped holder 23 when viewed from a plane which is manufactured of a material having conductivity. The holder 23 is also able to be manufactured of, for example, the same material as the target described later. On the lower surface of the holder 23, a plurality of concave portions 4 of a circular shape when viewed from a plane having the same opening area is formed. In the present embodiment, as shown in FIG. 9, firstly, one concave portion 4 is formed so as to be concentric with the center Cp of the holder 23, and six concave portions 4 are formed around this concave portion 4 on the same imaginary circumference Vc on the bases of the concave portion 4 so as to be situated at equal intervals. That is, in the present embodiment, one concave portion 4 formed in the center Cp of the holder 23, and six concave portions 4 formed on the circumference setting the center Cp of the holder 23 as the center of circle at equal intervals are shown as an example.

In the present embodiment, a configuration was described in which six concave portions 4 are formed therearound on the basis of the concave portion 4 formed on the center Cp of the holder, but six concave portions 4 may be formed therearound on the basis of each of the concave portions 4 on the imaginary circumference Vc respectively. In addition, similarly, a plurality of concave portions 4 may be formed outside of the holder 23 in a diameter direction (until the concave portions 4 cannot be formed), and the concave portions 4 may densely be formed over the whole lower surface of the holder 23. Accordingly, the area of the lower surface of the holder is set such that the center of the concave portion 4 situated in the outermost portion of the holder in the diameter direction is situated inside the outer periphery of the substrate W in the diameter direction. In addition, in the configuration shown in FIG. 9, the concave portions (six) of one cycle are formed therearound on the basis of the concave portion 4 formed in the center Cp of the holder, but it is not limited by this, the concave portions (for example, 12 or more) of 2 cycles or more may be formed therearound. In addition, for example, four or eight concave portions may be adopted without being limited to six concave portions in one cycle.

Furthermore, the gap between the concave portions 4 in the diameter direction is greater than the diameter of a cylindrical magnet described later, and is set in the range capable of maintaining the strength of the holder 23. Moreover, the targets 5 are inserted into each concave portion 4, and the targets 5 are fitted to each of the concave portions 4 from the bottom portion sides thereof in a freely attachable or detachable manner.

Furthermore, in the present embodiment, accommodation holes 6 are formed so that six magnets 7 are situated around one concave portion 4 at equal intervals and on a line connecting the centers of each concave portion 4 adjacent to each other (see FIG. 9). Each magnet 7 is designed so that the strong magnetic field of 500 gauss or more is generated in the internal space 5a of the target 5 upon being disposed around each concave portion 4.

By configuring the film forming apparatus 21 as mentioned above, in a case where the target 5 is sputtered, when the sputter particles scattered from the target 5 have the positive electric charge, the flying direction of the sputter particles is controlled by the vertical magnetic field from the target 5 to the substrate W, whereby the sputter particles are approximately vertically incident to and attached to the substrate W on the whole surface of the substrate W. That is, as indicated by an arrow in FIG. 7, according to the shape of the vertical line M of magnetic force that is locally generated from the sputter surface of the target 5 toward the substrate W at predetermined intervals, the flying direction is controlled so as to follow the direction of the line M of magnetic force, whereby the directivity is enhanced so that the coating is selectively formed only in a predetermined region (or the coating is not selectively formed in a predetermined region) as indicated by an arrow in FIG. 7.

As a consequence, when using the film forming apparatus 21 in the film forming process in the production of the semiconductor device, it is possible to realize an improvement in coverage ratio to the high aspect ratio micro groove or hole. In FIG. 7, by forming the film so as to have extremely high film thickness uniformity in a position facing the openings of the targets 5 which are placed in plural, it is possible to form the film even in the high aspect rate micro hole in a plurality of desired regions on the substrate W with satisfactory coating property.

### Example 1

Firstly, as Example 1, in order to confirm that the directivity of the sputter particles can be enhanced by adjusting the process pressure while generating the magnetic field so that the vertical line of magnetic force locally passes from the sputter surface of the target toward the surface to be film formed of the substrate at predetermined intervals, the process pressure in the chamber is changed to 0.12 Pa, 0.3 Pa, 0.6 Pa, 1.2 Pa, 1.6 Pa, 3.0 Pa, and 10.0 Pa and the film forming apparatus shown in FIG. 1 is used, thereby forming the Cu film on the substrate W.

In the present embodiment, as the substrate W, a material is used in which, after forming the silicon oxide film over the whole surface of the Si wafer of φ300 mm, an high aspect ratio micro hole (for example, width w is 45 nm, and depth d is 150 nm) is patterned and formed in the silicon oxide film by the known method.

Furthermore, as shown in FIG. 2, as the cathode unit, a holder made of Cu having a composition ratio of 99% and φ600 mm was used. Furthermore, a concave portion having an opening diameter of φ40 mm and a depth of 50 mm is formed in the center of the lower surface of the holder, and the target of the bottom portion cylinder manufactured from the same material as the holder was fitted into the concave portion from the bottom portion side. Furthermore, six magnet units are circumferentially equipped around the concave portion at equal intervals and are used as the cathode unit for Example 1. In this case, the magnet generates the magnetic field in the space of the concave portion at the magnetic field intensity of 500 gauss. Moreover, the cathode unit manufactured in this manner was attached to the ceiling portion of the vacuum chamber, and then, the mask member was mounted and covered on the lower surface of the holder except for the opening of the concave portion.

Furthermore, as the film forming condition, a distance between the lower surface of the holder and the substrate was set to 300 mm, Ar is used as the sputter gas, the input electric power to the target was set in the constant electric current control of 20 A, the sputter time was set to 20 seconds, and the film formation of the Cu film was performed.

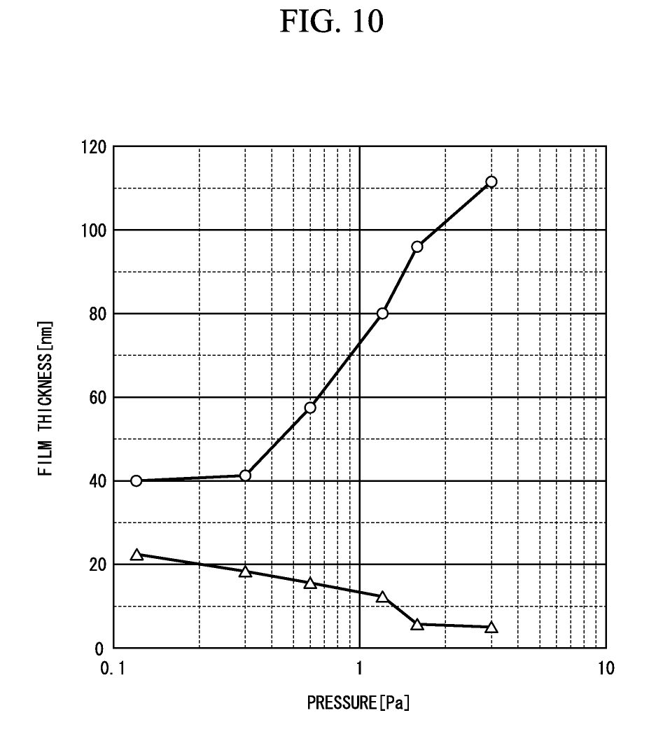

Moreover, a film thickness at the center position (0 mm) of the film formed substrate W and at the position separated by 70 mm from the center position are measured respectively. The results are indicated in Table 1. Furthermore, a relationship between the process pressure and the film thickness is shown in FIG. 10.

TABLE 1

| posi- | | | | | | | |
|---|---|---|---|---|---|---|---|
| tion | process pressure (Pa) | | | | | | |
| (mm) | 0.12 | 0.3 | 0.6 | 1.2 | 1.6 | 3.0 | 10.0 |
| 0 | 40.0 nm | 41.0 nm | 57.0 nm | 79.7 nm | 95.1 nm | 110.7 nm | no |
| | | | | | | | result |
| 70 | 22.2 nm | 18.9 nm | 15.2 nm | 11.7 nm | 3.0 nm | 2.3 nm | no |
| | | | | | | | result |

From the results of Table 1 and FIG. 10, it was confirmed that when the process pressure is equal to or greater than 0.3 Pa, the film thickness at the center position of the substrate is gradually increased, and the film can selectively be formed only in a predetermined region. Furthermore, it was confirmed that, between the process pressures of 1.2 Pa and 1.6 Pa, approximately, from near 1.5 Pa, the film thickness in the position separated by 70 mm from the center position of the substrate is reduced at once, and the directivity can be enhanced so as not to selectively form the film in a predetermined region. This is considered to be because, by setting the process pressure to 1.5 Pa or more, the hollow discharge voltage becomes constant (saturation), the sputter particles lose the directivity in the hollow, and the sputter particles are induced toward the substrate by the magnetic field generated from the sputter surface of the target toward the surface to be film formed of the substrate.

As a result, it is understood that, upon controlling the process pressure in the chamber to 0.3 Pa or more, preferably, 1.5 Pa or more, the directivity can be enhanced.

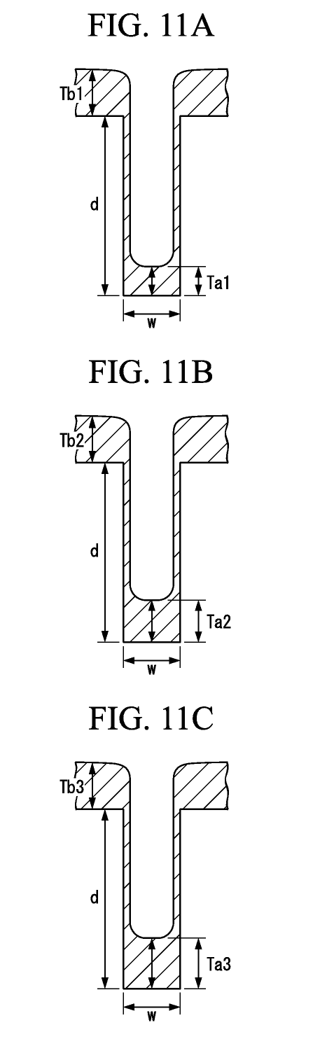

Furthermore, in the embodiment mentioned above, when the gas pressure in the chamber is (A) 0.12 Pa, (B) 0.6 Pa, and (C) 1.6 Pa, the film formation conditions in the micro hole are shown in FIGS. 11A to 11C as schematic cross-sectional views respectively, and a film thickness Ta to the surface around the micro hole and a film thickness Tb to the bottom surface of the micro hole are measured respectively, thereby calculating the bottom coverage (Tb/Ta).

As a consequence, when the gas pressure is (A) 0.12 Pa, a film thickness Ta1 to the surface around the micro hole was 40 nm, a film thickness Tb1 to the bottom surface of the micro hole was 24.3 nm, and the bottom coverage was 60.8%. Furthermore, when the gas pressure was (B) 0.6 Pa, a film thickness Ta2 to the surface around the micro hole was 40 nm, a film thickness Tb2 to the bottom surface of the micro hole was 35.0 nm, and the bottom coverage was 87.9%. In addition, when the gas pressure was (C) 1.6 Pa, a film thickness Ta3 to the surface around the micro hole was 40 nm, a film thickness Tb3 to the bottom surface of the micro hole was 42.4 nm, and the bottom coverage was 106%.

From FIGS. 11A to 11C and the results as above, it can be confirmed that, by raising the flow rate of the gas in the chamber, that is, by raising the gas pressure in the chamber, the directivity can be enhanced, whereby the film is selectively formed in a predetermined region and the coverage ratio is improved. Furthermore, from the results, it is understood that the sputter particles are obliquely scattered, whereby it is possible to greatly reduce the attachment and the deposition to the portion other than the surface to be film formed of the object to be processed such as the anti-attachment plate.

Next, in the Example 1, the bottom coverage of the coating, the directivity of the sputter particle, and the convergence of the sputter particles were evaluated respectively, upon setting the time when the pressure during film formation is equal to or less than 0.3 Pa to zone (A), setting the time when the pressure during film formation is equal to or greater than 0.3 Pa and equal to or less than 1.5 Pa to zone (B), setting the time when the pressure during film formation is equal to or greater 1.5 Pa and equal to or less than 10.0 to zone (C), and setting the time when the pressure during film formation is equal to or greater than 10.0 Pa to zone (D) and upon forming the film in each zone. The results are indicated in Table 2.

In addition, the results in each evaluation method are indicated as below.

When the bottom coverage was equal to or less than 50%, an NG sign was indicated, and when the bottom coverage was 50% to 80%, a B sign was indicated, when the bottom coverage is 80% to 100%, an F sign was indicated, and when the bottom coverage was equal to or greater than 100%, a G sign was indicated.

Furthermore, when the symmetry of the coverage was considerably increased by the directivity of the sputter particle, the NG sign was indicated, when the symmetry was high, the B sign was indicated, when the symmetry was about in the middle, the F sign was indicated, and when the symmetry was hardly confirmed, the G sign was indicated.

In addition, when the film thickness ratio in the position corresponding to the lower part of the eroded portion and the lower portion of the non-eroded portion was equal to or less than 1, the convergence of the sputter particles was indicated by the NG sign, when the film thickness ratio was about 1 to 2, the convergence was indicated by the B sign, and when the film thickness ratio was about 2 to 5, the convergence was indicated by F sign, and when the film thickness ratio was equal to or greater than 5, the convergence was indicated by the G sign.

TABLE 2

| | | zone (B) | zone (C) | |
|---|---|---|---|---|
| | zone (A) | 0.3 Pa to | 1.5 Pa to | zone (D) |
| process pressure | <0.3 Pa | 1.5 Pa | 10.0 Pa | 10.0 Pa< |
| bottom coverage | B | F | G | B to NG |
| directivity of sputter | B | F | G | F to NG |
| particle | | | | |
| convergence of | B | B to F | G | B to NG |
| sputter particle | | | | |

By the results indicted in Table 2, by controlling the gas pressure in the range from 0.3 Pa to 10.0 Pa, it can be confirmed that any of each item of the bottom coverage, the directivity of the sputter particle, and the convergence of the sputter particles was desirably evaluated.

Thus, it is understood that the sputter particles can be induced onto the surface to be film formed of the substrate, and can be deposited and the film can be deposited while controlling the flying direction of the generated sputter particles, by introducing the sputter gas into the chamber while generating the magnetic field so that the vertical line of magnetic field locally passes from the sputter surface of the target toward the surface to be film formed of the substrate at predetermined intervals, and controlling the gas pressure in the chamber in the range of 0.3 Pa to 10.0 Pa, preferably, in the range of 1.5 Pa to 10.0 Pa to sputter the target.

### Example 2

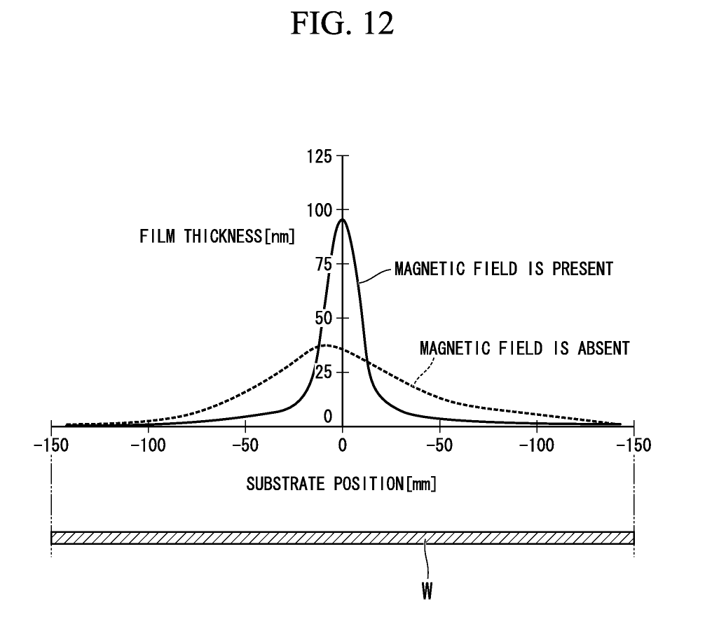

Next, in order to confirm that the flying direction of the sputter particles can be controlled by adjusting the intensity of the magnetic field, under the same film formation condition as Example 1, the process pressure was set to 1.6 Pa (the gas flow rate was 267 sccm) at which a preferable result could be obtained in Example 1, and the film thickness of the substrate in the position in the diameter direction was measured when the film was formed while generating the vertical magnetic field from the sputter surface of the target toward the surface to be film formed of the substrate and when the film was formed while not generating the vertical magnetic field. Moreover, the film thickness distribution indicating the relationship between the substrate position and the film thickness at this time is shown in FIG. 12 respectively.

As shown in FIG. 12, it was confirmed that, when the film is formed while generating the vertical magnetic field, the film is locally formed in a predetermined radius region (approximately the same region as the eroded diameter of the target) from the substrate center. However, it was confirmed that, when the vertical magnetic field is not generated, the sputter particles are scattered and deposited on the region equal to or greater than the eroded diameter in the target.

Thus, it is understood that the flying direction of the sputter particles can be controlled by adjusting the intensity of the magnetic field.

In addition, in the present embodiment, a case was described where the hollow type target is used, but the present invention is not limited thereto. Thus, if the sputter gas is introduced into the chamber, while generating the magnetic field such that the vertical line of magnetic force locally passes from the sputter surface of the target toward the surface to be film formed of the object to be processed at predetermined intervals, and the gas pressure in the chamber is controlled in the range from 0.3 Pa to 10.0 Pa, the present invention can also be performed in the case of using the plane type target.

As described above, the film forming method according to the present invention will schematically be described.

In the film forming method of forming the film on the surface of the object to be processed, the object to be processed W and the target 5 are disposed so as to face each other in the chamber 2 having an internal space capable of reducing the pressure, and the magnetic field is generated such that the vertical line of magnetic force locally passes from the sputter surface of the target toward the surface to be film formed of the object to be processed at predetermined intervals. Next, the sputter gas is introduced into the chamber, the gas pressure in the chamber is controlled in the range from 0.3 Pa to 10.0 Pa, and, by applying the negative direct voltage to the target, and the plasma is generated in the space between the target and the object to be processed. Moreover, the sputter particles are induced to and deposited on the object to be processed while controlling the flying direction of the sputter particles generated by sputtering the target, and the film is formed on the surface of the object to be processed.

As mentioned above, by adjusting the intensity of the magnetic field, the flying direction of the sputter particles can be controlled. In addition, in the central region and the peripheral region of the object to be processed, the intervals between the vertical line of magnetic force may be identical to each other and be different from each other.

### INDUSTRIAL APPLICABILITY

The film forming apparatus and the film forming method of the present invention can widely be used in the film formation to the high aspect ratio micro groove or hole. In addition, the film forming apparatus and the film forming method of the present invention is able to improve the coverage ratio and extend the maintenance cycle of the film forming apparatus.

### REFERENCE SIGNS LIST

W SUBSTRATE (OBJECT TO BE PROCESSED)
1, 21 FILM FORMING APPARATUS
2 CHAMBER
3, 23 HOLDER
4 CONCAVE PORTION
5 TARGET
5A DISCHARGE SPACE
6 A ACCOMMODATION HOLE
7 MAGNET (FIRST MAGNETIC FIELD GENERATING MECHANISM)
8 SUPPORT PLATE
9 DIRECT CURRENT POWER SOURCE (DC POWER SOURCE)
10 STAGE
11 GAS PIPE (GAS INTRODUCTION MECHANISM)
12 EXHAUST PUMP (EXHAUST MECHANISM)
13U UPPER COIL (SECOND MAGNETIC FIELD GENERATING MECHANISM)
13D LOWER COIL (SECOND MAGNETIC FIELD GENERATING MECHANISM)
14 YOKE
15 LEAD WIRE
16 POWER SOURCE DEVICE

What is claimed is:

1. A film forming method of forming a coating on a surface of an object to be processed comprising:
disposing a target forming a base material of the coating and the object to be processed in a chamber so as to face each other, and generating a magnetic field through which a vertical line of magnetic force locally passes from a sputter surface of the target toward a surface to be film formed of the object to be processed at predetermined intervals;
generating plasma in a space between the target and the object to be processed by introducing a sputter gas into the chamber, controlling a gas pressure in the chamber to a range of 0.3 Pa to 10.0 Pa, and applying a negative DC voltage to the target; and
inducing and depositing sputter particles on the object to be processed and forming the coating, while controlling flying directions of the sputter particles generated by sputtering the target.

2. The film forming method according to claim 1, wherein the flying directions of the sputter particles are controlled by adjusting intensity of the magnetic field.

3. The film forming method according to claim 1, wherein the intervals between the vertical lines of magnetic force are identical in a central region and a peripheral region of the object to be processed.

4. The film forming method according to claim 1, wherein the intervals between the vertical lines of magnetic force are different in a central region and a peripheral region of the object to be processed.

5. A film forming apparatus that forms a coating on a surface of an object to be processed, comprising:
a chamber in which a target forming a base material of the coating and the object to be processed are disposed so as to face each other and which has an internal space to house the target and the object to be processed therein;
an exhaust mechanism that decompresses an inner portion of the chamber;
a first magnetic field generating mechanism that generates a magnetic field in a front space when viewed from a sputter surface of the target;
a gas introducing mechanism that includes a function of adjusting a flow rate of a sputter gas to be introduced into the chamber;
a DC power source that applies a negative DC voltage to the target; and
a second magnetic field generating mechanism that generates a magnetic field through which a vertical line of magnetic force locally passes from the sputter surface of the target toward a surface to be film formed of the object to be processed at predetermined intervals.

6. The film forming apparatus according to claim 5, further comprising:
a holder in which one or more concave portions are provided at one surface thereof,
wherein the target forms a cylindrical shape having a bottom, and is mounted on the concave portion of the holder from a bottom portion side of the target, and
the first magnetic field generating mechanism is assembled to the holder so as to generate the magnetic field in an internal space of the target.
